(19) United States
(12) Patent Application Publication
(10) Pub. No.: US 2025/0089513 A1
(43) Pub. Date: Mar. 13, 2025

(54) Display Substrate, Manufacturing Method Therefor, and Display Device

(71) Applicant: BOE Technology Group Co., Ltd., Beijing (CN)

(72) Inventors: Ying CUI, Beijing (CN); Donghui YU, Beijing (CN); Cheng XU, Beijing (CN); Dandan ZHOU, Beijing (CN)

(21) Appl. No.: 18/557,297

(22) PCT Filed: Feb. 28, 2023
(86) PCT No.: PCT/CN2023/078691

§ 371 Date: Oct. 26, 2023

(51) Int. Cl. H10K 59/38; H10K 59/80

(52) U.S. Cl. CPC H10K 59/38; H10K 59/879

(57) ABSTRACT

A display substrate, a manufacturing method therefor, and a display device. The display substrate includes: a base substrate; a light-emitting substrate disposed on the base substrate and the light-emitting substrate being configured to emit incident light; a color conversion layer disposed at a side of the light emitting substrate away from the base substrate and the color conversion layer being configured to convert the incident light emitted from the light emitting substrate into light of a specific color; a selective reflection layer disposed on a side of the color conversion layer away from the base substrate and the selective reflection layer being configured to reflect incident light not converted by the color conversion layer to the color conversion layer and to transmit light of the specific color converted by the color conversion layer.

### CROSS-REFERENCE TO RELATED APPLICATION

The present application is a U.S. National Phase Entry of International Application PCT/CN2023/078691 having an international filing date of Feb. 28, 2023, and entitled “Display Substrate, Manufacturing Method Therefor, and Display Device”, the contents of which are hereby incorporated herein by reference in their entireties.

### TECHNICAL FIELD

The present disclosure relates to, but is not limited to, the field of display technologies, and in particular to a display substrate, a method for manufacturing the display substrate, and a display device.

### BACKGROUND

OLED display technology has characteristics such as self-luminescence, wide viewing angle, wide color gamut, high contrast, lightness and thinness, foldability, bendability, portability, etc., and has become a main direction for research and development in the field of display.

In QD (Quantum Dot) technology, semiconductor particles on the nanometer scale are used to generate light of specific frequency by applying a certain electric field or light pressure on them. A light emitting frequency is related to a diameter of the particles, so the frequency of light, that is, the color of light, can be adjusted by adjusting the diameter of the particles. R/G/B peak width at half-height of a spectrum emitted by quantum dots is narrower than that of a spectrum of a self-luminescence OLED, the spectrum is purer and with a higher color saturation.

In the QD-OLED technology, blue OLED backlight is used to excite quantum dots, which can generate red and green light of corresponding wavelengths, thereby achieving a purpose of realizing high color gamut and high picture quality performance. At present, in QD-OLED display devices, quantum dots cannot completely absorb the backlight emitted by the OLEDs, which affects a display effect of the display devices.

### SUMMARY

The following is a summary of subject matter described herein in detail. The summary is not intended to limit the protection scope of claims.

In a first aspect, an embodiment of the present disclosure provides a display substrate, which includes:
a base substrate;
a light emitting substrate disposed on the base substrate and the light emitting substrate being configured to emit incident light;
a color conversion layer disposed at a side of the light emitting substrate away from the base substrate and the color conversion layer being configured to convert the incident light emitted from the light emitting substrate into light of a specific color; and
a selective reflection layer disposed on a side of the color conversion layer away from the base substrate and the selective reflection layer being configured to reflect incident light which has not been converted by the color conversion layer to the color conversion layer, and to transmit the light of the specific color converted by the color conversion layer.

In some exemplary embodiments, the selective reflection layer includes microlenses and an orthographic projection of the microlenses on the base substrate is overlapped with an orthographic projection of the color conversion layer on the base substrate.

In some exemplary embodiments, a shape of the microlenses includes at least one of cone, hemisphere or pyramid.

In some exemplary embodiments, densities of the microlenses are different.

In some exemplary embodiments, the selective reflection layer includes a first microlens area and a second microlens area, each of the first microlens area and the second microlens area includes at least one microlens, the color conversion layer includes a first color conversion pattern and a second color conversion pattern, the first color conversion pattern is configured to convert the incident light emitted from the light emitting substrate into red light, the second color conversion pattern is configured to convert the incident light emitted from the light emitting substrate into green light, an orthographic projection of the first microlens area on the base substrate is overlapped with an orthographic projection of the first color conversion layer on the base substrate, an orthographic projection of the second microlens area on the base substrate is overlapped with an orthographic projection of the second color conversion layer on the base substrate, and a density of the at least one microlens in the second microlens area is greater than a density of the at least one microlens in the first microlens area.

In some exemplary embodiments, the display substrate further includes a cover plate, the cover plate is disposed on the side of the color conversion layer away from the base substrate, and the selective reflection layer is disposed on a surface of the cover plate away from the base substrate.

In some exemplary embodiments, the microlenses protrude in a direction away from the base substrate.

In some exemplary embodiments, the display substrate further includes a color resistance layer, the color resistance layer is disposed on a side of the selective reflection layer away from the base substrate, surfaces of the microlenses away from the base substrate is in contact with a surface of the color resistance layer close to the base substrate, or a first gap is provided between the surfaces of the microlenses away from the base substrate and the surface of the color resistance layer close to the base substrate.

In some exemplary embodiments, the display substrate further includes a color resistance layer, the color resistance layer is disposed on a side of the selective reflection layer away from the base substrate, and the selective reflection layer is disposed on a surface of the color resistance layer close to the base substrate.

In some exemplary embodiments, the microlenses protrude in a direction close to the base substrate.

In some exemplary embodiments, the display substrate further includes a cover plate, the cover plate is disposed between the selective reflection layer and the color conversion layer, surfaces of the microlenses close to the base substrate is in contact with a surface of the cover plate away from the base substrate, or a second gap is provided between the surfaces of the microlenses close to the base substrate and the surface of the cover plate away from the base substrate.

In some exemplary embodiments, the display substrate further includes a color resistance layer and a cover plate, the color resistance layer is disposed on a side of the color conversion layer away from the base substrate, and the cover plate is disposed on a side of the cover plate away from the base substrate, the display substrate includes a first selective reflection layer and a second selective reflection layer, the first selective reflection layer is disposed on a surface of the cover plate away from the base substrate, and the second selective reflection layer is disposed on a surface of the color resistance layer close to the base substrate.

In some exemplary embodiments, each of the first selective reflection layer and the second selective reflection layer includes microlenses, the microlenses of the first selective reflection layer protrude in a direction away from the base substrate, and the microlenses of the second selective reflection layer protrude in a direction close to the base substrate.

In some exemplary embodiments, the microlenses of the first selective reflection layer and the microlenses of the second selective reflection layer are alternately disposed in a direction parallel to the base substrate.

In some exemplary embodiments, a third gap is provided between a surface of the microlenses of the first selective reflection layer away from the base substrate and the surface of the color resistance layer close to the base substrate.

In some exemplary embodiments, a fourth gap is provided between surfaces of the microlens of the second selective reflection layer close to the base substrate and the surface of the cover plate away from the base substrate.

In some exemplary embodiments, the selective reflection layer includes at least two plating films and the at least two plating films are disposed sequentially along a thickness direction of the base substrate.

In some exemplary embodiments, the plating films are made of a metal or an inorganic material.

In some exemplary embodiments, the plating films include at least one of titanium, tantalum, zirconium, niobium, aluminum, magnesium, iridium, yttrium, ytterbium, indium, tungsten, molybdenum, vanadium, nickel, silver, copper and gold.

In some exemplary embodiments, the plating films include at least one of silicon, oxide, nitride, fluoride, or nitrogen oxide.

In another aspect, the present disclosure further provides a display device, including the display substrate described above.

In another aspect, the present disclosure further provides a method for manufacturing a display substrate, including:
forming a light emitting substrate on the base substrate and the light emitting substrate being configured to emit incident light;
forming a color conversion layer on a side of the light emitting substrate away from the substrate and the color conversion layer being configured to convert the incident light emitted from the light emitting substrate into light of a specific color; and
forming a selective reflection layer on a side of the color conversion layer away from the base substrate and the selective reflection layer being configured to reflect the incident light which has not been converted by the color conversion layer to the color conversion layer and to transmit the light of the specific color converted by the color conversion layer.

Other aspects may become clear after the accompanying drawings and the detailed description are read and understood.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and not intended to form limitations on the technical solutions of the present application.

FIG. 1 is a schematic plan view of a structure of a display substrate according to an embodiment of the present disclosure.

FIG. 2 is a first cross-sectional view of a display substrate according to an embodiment of the present disclosure.

FIG. 3 is a schematic diagram of a cross sectional structure of a light emitting substrate of a display substrate according to an embodiment of the present disclosure.

FIG. 4 is a second cross-sectional view of a display substrate according to an embodiment of the present disclosure.

FIG. 5 is a third cross-sectional view of a display substrate according to an embodiment of the present disclosure.

### DETAILED DESCRIPTION

To make objectives, technical solutions, and advantages of the present disclosure clearer, embodiments of the present disclosure will be described in detail with reference to the accompanying drawings. It is to be noted that implementations may be practiced in multiple different forms. Those of ordinary skills in the art may easily understand such a fact that implementations and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict.

Sometimes for the sake of clarity, sizes of various constituent elements, thicknesses of layers or areas in the drawings may be exaggerated. Therefore, one implementation of the present disclosure is not necessarily limited to the sizes, and shapes and sizes of various components in the drawings do not reflect actual scales. In addition, the drawings schematically illustrate ideal examples, and one implementation of the present disclosure is not limited to shapes, numerical values, or the like shown in the drawings.

Ordinal numerals such as “first”, “second”, and “third” in the specification are set to avoid confusion between constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are configured to illustrating positional relationships between constituent elements with reference to the drawings, and are merely for facilitating describing of the specification and simplifying the description, rather than indicating or implying that a referred device or element must have a particular orientation and be constructed and operated in the particular orientation. Therefore, they cannot be understood as limitations on the present disclosure. The positional relationships between the constituent elements are changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection; it may be a mechanical connection or an electrical connection; and it may be a direct mutual connection, or an indirect connection through a middleware, or an internal communication between two elements. Those of ordinary skills in the art may understand specific meanings of these terms in the present disclosure according to specific situations.

In the specification, a transistor refers to an element which at least includes three terminals, i.e., a gate electrode, a drain electrode and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode; or, the first electrode may be a source electrode, and the second electrode may be a drain electrode. In cases that transistors with opposite polarities are used, a current direction changes during operation of a circuit, or the like, functions of the “source electrode” and the “drain electrode” are sometimes interchanged. Therefore, the “source electrode” and the “drain electrode” are interchangeable in the specification.

In the specification, “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” refers to that a boundary is defined not so strictly and numerical values within process and measurement error ranges are allowed.

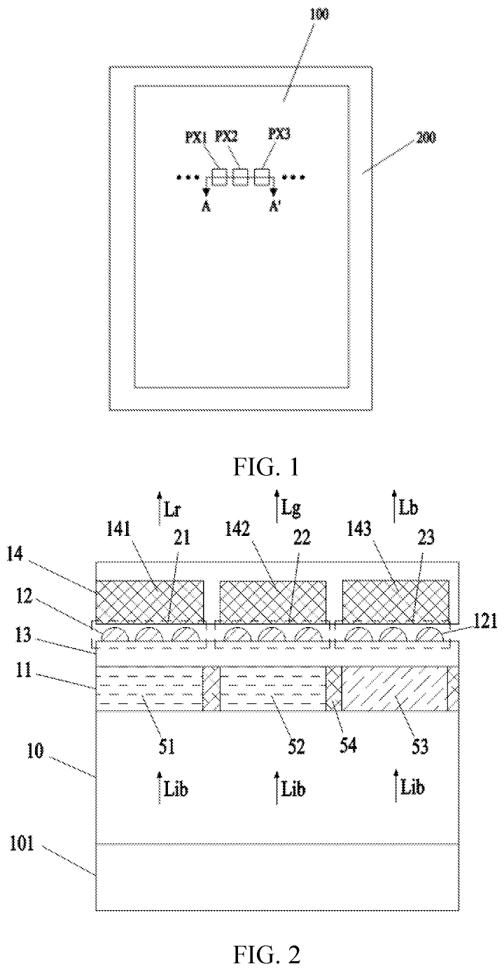

FIG. 1 is a schematic plan view of a structure of a display substrate according to an embodiment of the present disclosure. In some exemplary embodiments, as shown in FIG. 1, a display substrate may include a display area 100 and a non-display area 200. The display area 100 is configured to display an image. The display area 100 includes multiple sub-pixels arranged regularly and the sub-pixels are configured to emit light. For example, the display area 100 includes multiple first sub-pixels PX1, multiple second sub-pixels PX2 and multiple third sub-pixels PX3 which are arranged regularly. The first sub-pixels PX1 may be red (R) sub-pixels, the second sub-pixels PX2 may be green (G) sub-pixels, and the third sub-pixels PX3 may be blue (B) sub-pixels. The display substrate may provide an image using the multiple sub-pixels in the display area 100. An image is not displayed in the non-display area 200 and the non-display area 200 may completely or partially surround the display area 100. The non-display area 200 may include a driver or the like, which is configured to provide electrical signals or electrical power to the sub-pixels.

In an exemplary implementation embodiment, as shown in FIG. 1, the display substrate includes a display area 100 with a rectangular shape. In some embodiments, the display area 100 may also be in a shape of a circle, an ellipse or a polygon such as a triangle, a pentagon, a hexagon or an octagon.

In some exemplary embodiments, the display substrate may be a flat display substrate. In some embodiments, the display substrate may be other types of display substrates, such as a flexible display substrate, a foldable display substrate, a rollable display substrate.

In some exemplary embodiments, each sub-pixel may include a light emitting substrate and a color conversion layer. The light emitting substrate is configured to supply incident light Lib to the color conversion layer, and the color conversion layer is configured to convert the incident light Lib emitted by the light emitting substrate into light of a specific color. For example, the light emitting substrate may emit blue incident light Lib to the color conversion layer and the color conversion layer may convert the blue incident light Lib into red light or green light.

In some exemplary embodiments, the light emitting substrate may include a pixel circuit and a light emitting device. The light emitting device may include one of an organic light emitting diode (OLED), a micro light emitting diode (MLED) and a quantum dot light emitting diode (QLED). Among them, the light emitting device in the light emitting substrate can emit blue light.

In some exemplary embodiments, a shape of the light emitting device of a sub-pixel may be a rectangle, a rhombus, a pentagon, or a hexagon.

In some exemplary embodiments, a pixel circuit of a sub-pixel is configured to receive a data voltage transmitted by a data signal line under control of a scan signal line and a light emitting control line, and output a corresponding current to the light emitting device. The light emitting device in each sub-pixel is connected to a pixel circuit of the sub-pixel where the light emitting device is located and the light emitting device is configured to emit light with a corresponding brightness in response to a current output by the pixel circuit of the sub-pixel where the light emitting device is located.

FIG. 2 is a first cross-sectional view of a display substrate according to an embodiment of the present disclosure. FIG. 2 may be a cross-sectional view taken along an A-A′ direction in FIG. 1. FIG. 2 illustrates a cross-sectional view of one first pixel, one second sub-pixel and one third pixel. In some exemplary embodiments, the display substrate according to the embodiment of the present disclosure may include more sub-pixels (see FIG. 1). Although the first pixel to the third pixel are shown to be adjacent to each other in FIG. 2 and the embodiments of the present disclosure is not limited thereto. That is to say, other components such as wires may be between the first pixel to the third pixel. The first pixel, the second sub-pixel and the third pixel may be pixels that are not adjacent to each other. In FIG. 2, cross sections of the first pixel to the third pixel may not be cross sections in a same direction of the display substrate.

In some exemplary embodiments, as shown in FIG. 2, the display substrate according to the embodiment of the present disclosure may include a base substrate 101 and a light emitting substrate 10, a color conversion layer 11, a cover plate 13, a selective reflection layer 12, and a color resistance layer 14 arranged sequentially in a direction away from the base substrate 101. The light emitting substrate 10 is disposed on the base substrate 101 and is configured to emit incident light Lib to the color conversion layer 11. The color conversion layer 11 is disposed on a side of the light emitting substrate 10 away from the base substrate 101 and is configured to convert the incident light Lib emitted from the light emitting substrate 10 into light of a specific color. The cover plate 13 is disposed on a side of the color conversion layer 11 away from the base substrate 101 for protecting the color conversion layer 11 and the light emitting substrate 10. The color resistance layer 14 is disposed on a side of the cover plate 13 away from the base substrate 101 and is configured to convert incident light Lib that has not been converted by the color conversion layer 11 into light of a specific color. The selective reflection layer 12 is disposed on the side of the color conversion layer 11 away from the base substrate 101, located between the cover plate 13 and the color resistance layer 14, and is configured to reflect the incident light Lib that has not been converted by the color conversion layer 11 to the color conversion layer 11 which converts the incident light Lib into light of a specific color, and is configured to transmit the light of the specific color converted by the color conversion layer 11.

The display substrate according to the embodiment of the present disclosure can reflect the incident light Lib (e.g. blue light) which has not been converted by the color conversion layer 11 to the color conversion layer 11 through the selective reflection layer 12, and convert the incident light Lib (e.g. blue light) into light of a specific color (e.g. red light or green light) through the color conversion layer 11, thereby improving an utilization rate of the incident light Lib emitted from the light emitting substrate 10 and improving a problem of backlight leakage of the display substrate. Moreover, the selective reflection layer 12 can transmit the light of the specific color converted by the color conversion layer 11 (for example, red light and green light), thereby preventing the selective reflection layer 12 from affecting a light output rate of the light of the specific color converted by the color conversion layer 11. The display substrate according to the embodiment of the present disclosure has a simple structure and is easy for mass production.

In some exemplary embodiments, the base substrate 101 may be a flexible base substrate, or may be a rigid base substrate.

The light emitting device in the display substrate in accordance with this embodiment being an organic light emitting diode (OLED) will be described as an example hereinafter, but the display substrate in accordance with this embodiment is not limited thereto. In another embodiment, the light emitting device in the display substrate may be a micro light emitting diode (MLED) or a quantum dot light emitting diode (QLED). For example, a light emitting layer of the light emitting device in the display substrate may include an organic material, an inorganic material, quantum dots, an organic material and quantum dots, an inorganic material and quantum dots, or an organic material, an inorganic material and quantum dots.

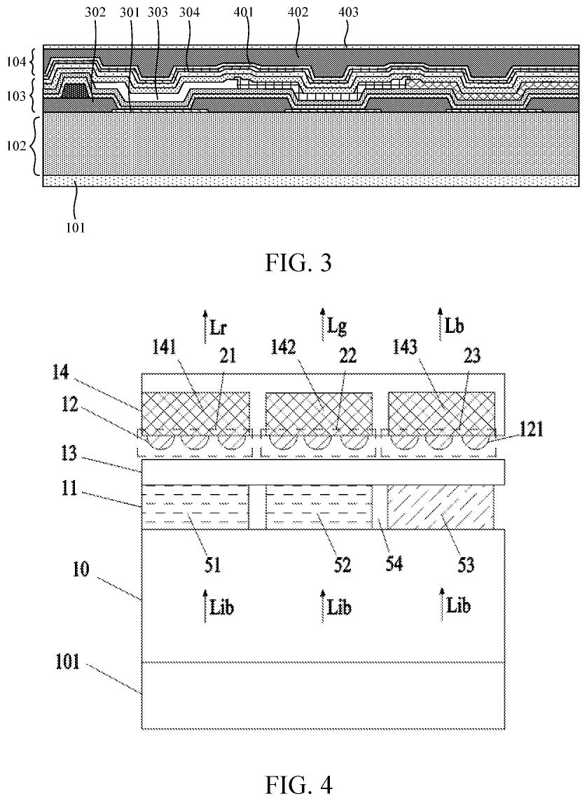

FIG. 3 is a schematic diagram of a cross sectional structure of a light emitting substrate of a display substrate according to an embodiment of the present disclosure. As shown in FIG. 3, in a direction perpendicular to the display substrate, the light emitting substrate 10 may include a drive circuit layer 102, a light emitting structure layer 103 and an encapsulation structure layer 104 that are sequentially arranged on a base substrate 101.

In some exemplary embodiments, the drive circuit layer 102 may include a pixel circuit composed of multiple transistors and capacitors. The light emitting structure layer 103 includes at least one light emitting device, and each light emitting device may include at least an anode 301, a pixel definition layer 302, an organic emitting layer 303 and a cathode 304. The anode 301 is connected with the pixel circuit, the organic emitting layer 303 is connected with the anode 301, the cathode 304 is connected with the organic emitting layer 303, and the organic emitting layer 303 emits light of a corresponding color under driving of the anode 301 and the cathode 304. The encapsulation structure layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 to form a stacked structure of inorganic material/organic material/inorganic material, which ensures that external moisture cannot enter the light emitting structure layer 103.

In some exemplary embodiments, the first encapsulation layer 401 and the third encapsulation layer 403 may each include one or more inorganic insulation materials. An inorganic insulation material may include one of aluminum oxide, titanium oxide, tantalum oxide, hafnium oxide, zinc oxide, silicon oxide, silicon nitride and/or silicon oxynitride. The first encapsulation layer 401 and the third encapsulation layer 403 may be formed by chemical vapor deposition. The second encapsulation layer 402 may be made of a polymer material. The polymer-based material may include one of acrylic resin, epoxy resin, polyimide, and polyethylene.

In some exemplary embodiments, the organic emitting layer 303 may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In some examples, one or more layers of hole injection layers, hole transport layers, electron block layers, hole block layers, electron transport layers, and electron injection layers of all sub-pixels may be a common layer communicated together. Light emitting layers of adjacent sub-pixels may be overlapped slightly, or may be mutually isolated.

In some exemplary embodiments, the light emitting device in the light emitting substrate 10 may provide incident light Lib incident on the color conversion layer 11 and the incident light Lib emitted from the light emitting device may pass through the encapsulation layer 104 to enter the color conversion layer 11.

In some exemplary embodiments, as shown in FIG. 2, the color conversion layer 11 may include a first color conversion pattern 51, a second color conversion pattern 52, a light transmission pattern 53, and a light blocking pattern 54 located on a circumferential side of the first color conversion pattern 51, a circumferential side of the second color conversion pattern 52, and a circumferential side of the light transmission pattern 53. An orthographic projection of the first color conversion pattern 51 on the base substrate 101 is overlapped with an orthographic projection of the light emitting devices of the light emitting substrate 10 on the base substrate 101, an orthographic projection of the second color conversion pattern 52 on the base substrate 101 is overlapped with the orthographic projection of the light emitting devices of the light emitting substrate 10 on the base substrate 101, and an orthographic projection of the light transmission pattern 53 on the base substrate 101 is overlapped with the orthographic projection of the light emitting devices of the light emitting substrate 10 on the base substrate 101, so that the incident light Lib emitted from the light emitting substrate 10 can be incident to the first color conversion pattern 51, the second color conversion pattern 52, and the light transmission pattern 53. The incident light Lib emitted from the light emitting substrate 10 may be blue light, the incident light Lib emitted from the light emitting substrate 10 is converted into first color light (e.g. red light) through the first color conversion pattern 51, the incident light Lib emitted from the light emitting substrate 10 is converted into second color light (e.g. green light) through the second color conversion pattern 52, and the incident light Lib emitted from the light emitting substrate 10 is transmitted through the light transmission pattern 53.

In an exemplary embodiment, the light blocking pattern 54 may be in various colors, including black or white. For example, the light blocking pattern 54 may be black and may include a black matrix. The light blocking pattern 54 may be made of a light blocking material, which may include an opaque inorganic insulation material (e.g., chromium oxide or molybdenum oxide) or an opaque organic insulation material (e.g., black resin). As another example, the light blocking pattern 54 may be made of an organic insulation material such as a white resin.

In some exemplary embodiments, the light blocking pattern 54 may prevent color blending between light beams converted or transmitted in the first color conversion pattern 51, the second color conversion pattern 52 and the light transmission pattern 53 that are adjacent to each other.

In some exemplary embodiments, the first color conversion pattern 51 may convert blue incident light Lib emitted by the light emitting substrate 10 into red light Lr. The first color conversion pattern 51 may be made of a first photosensitive polymer with first quantum dots dispersed therein. The first photosensitive polymer may include an organic material, such as polysiloxane resin or epoxy resin, which has light transmission properties. The first quantum dots are excited by the blue incident light Lib to isotropically emit the red light Lr with a wavelength longer than a wavelength of the blue light. The first quantum dots may include a Group II-VI compound, a Group III-V compound, a Group IV-VI compound, a Group IV compound or a combination thereof.

In some exemplary embodiment, the second color conversion pattern 52 may convert the blue incident light Lib emitted by the light emitting substrate 10 into green light Lg. The second color conversion pattern 52 may include a second photosensitive polymer with second quantum dots dispersed therein. The second photosensitive polymer may be a same material as the first photosensitive polymer. The second quantum dots may include a Group II-VI compound, a Group III-V compound, a Group IV-VI compound, a Group IV compound or a combination thereof. A size of the second quantum dots may be smaller than a size of the first quantum dots, the second quantum dots may be excited by the blue incident light Lib and emit light with a wavelength greater than a wavelength of the blue light, and may isotropically emit the green light Lg with a wavelength less than a wavelength of the red light Lr.

In some exemplary embodiments, the light transmission pattern 53 may transmit the blue incident light Lib emitted by the light emitting substrate 10. The light transmission pattern 53 may be made of a third photosensitive polymer and the third photosensitive polymer includes scattering particles dispersed therein. The light transmission pattern 53 does not include individual quantum dots that can be excited by the blue incident light Lib. The third photosensitive polymer may include an organic material with light transmission properties, and the scattering particles may include titanium oxide particles or metal particles. The blue incident light Lib incident on the light transmission pattern 53 may be transmitted through the light transmission pattern 53 without color change, and the light emitted through the light transmission pattern 53 may be blue light Lb. The light transmission pattern 53 can transmits blue incident light Lib without changing its color, so as to obtain higher light efficiency.

In some exemplary embodiments, as shown in FIG. 2, the cover plate 13 may be a glass cover plate. An orthographic projection of the cover plate 13 on the base substrate 101 is overlapped with an orthographic projection of the color conversion layer 11 on the base substrate 101. For example, the orthographic projection of the cover plate 13 on the base substrate 101 is overlapped with each of the orthographic projection of the first color conversion pattern 51 on the base substrate 101, the orthographic projection of the second color conversion pattern 52 on the base substrate 101, the orthographic projection of the light transmission pattern 53 on the base substrate 101, and the orthographic projection of the light blocking pattern 54 on the base substrate 101.

In some exemplary embodiments, as shown in FIG. 2, the color resistance layer 14 is located on a side of the color conversion layer 11 away from the light emitting substrate 10. The first color conversion pattern 51, the second color conversion pattern 52 and the light transmission pattern 53 may convert the incident light Lib provided by the light emitting substrate 10 into light of a specific color or transmits the incident light Lib, and may emit the light towards the color resistance layer 14. The color resistance layer 14 can further absorb the incident light Lib provided by the light emitting substrate to improve the light output rate of the display substrate.

In some exemplary embodiments, the color resistance layer 14 includes a first color resistance pattern 141, a second color resistance pattern 142, and a third color resistance pattern 143. An orthographic projection of the first color resistance pattern 141 on the base substrate is overlapped with an orthographic projection of the first color conversion pattern 51 on the base substrate 101, for example, the orthographic projection of the first color resistance pattern 141 on the base substrate coincides with the orthographic projection of the first color conversion pattern 51 on the base substrate 101. The first color resistance pattern 141 can convert the blue incident light Lib, which has not been converted by the first color conversion pattern 51, into red light Lr. An orthographic projection of the second color resistance pattern 142 on the base substrate is overlapped with an orthographic projection of the second color conversion pattern 52 on the base substrate 101, for example, the orthographic projection of the second color resistance pattern 142 on the base substrate coincides with the orthographic projection of the second color conversion pattern 52 on the base substrate 101. The second color resistance pattern 142 can convert the blue incident light Lib, which has not been converted by the second color conversion pattern 52, into green light Lg. An orthographic projection of the third color resistance pattern 143 on the base substrate is overlapped with an orthographic projection of the light transmission pattern 53 on the base substrate 101, for example, the orthographic projection of the third color resistance pattern 143 on the base substrate coincides with the orthographic projection of the light transmission pattern 53 on the base substrate 101. The third color block pattern 143 can transmit the blue incident light Lib. The display substrate of the embodiment of the present disclosure can further absorb the blue incident light Lib through the color resistance layer 14 to improve the light output rate of the display substrate.

In some exemplary embodiments, as shown in FIG. 2, the selective reflection layer 12 is located between the cover plate 13 and the color resistance layer 14. An orthographic projection of the selective reflection layer 12 on the base substrate is overlapped with the orthographic projection of the color conversion layer 11 on the base substrate 101. For example, the orthographic projection of the selective reflection layer 12 on the base substrate 101 is at least overlapped with the orthographic projection of the first color conversion pattern 51 on the base substrate 101 and the orthographic projection of the second color conversion pattern 52 on the base substrate 101.

In some exemplary embodiments, the selective reflection layer 12 may reflect incident light Lib which has not been converted by the color conversion layer 11 to the color conversion layer 11 to convert the incident light into light of a specific color by the color conversion layer 11, and transmit the light of the specific color converted by the color conversion layer 11. For example, the selective reflection layer 12 may reflect the blue incident light Lib which has not been converted by the first color conversion pattern 51 to the first color conversion pattern 51, so that the blue incident light Lib is converted into the red light Lr by the first color conversion pattern 51, and the selective reflection layer 12 may transmit the red light Lr converted by the first color conversion pattern 51, thereby avoiding the selective reflection layer 12 from affecting a light output rate of the red light Lr. The selective reflection layer 12 can reflect the blue incident light Lib which has not been converted by the second color conversion pattern 52 to the second color conversion pattern 52, so that the blue incident light Lib is converted into the green light Lg by the second color conversion pattern 52, and the selective reflection layer 12 may transmit the green light Lg converted by the second color conversion pattern 52, thereby avoiding the selective reflection layer 12 from affecting the light output rate of the green light Lg.

The display substrate of the embodiment of the present disclosure can reflect the incident light Lib (e.g. blue light) which has not been converted by the color conversion layer 11 to the color conversion layer 11 through the selective reflection layer 12, and convert the incident light Lib (e.g. blue light) into light of a specific color (e.g. red light or green light) through the color conversion layer 11, thereby improving the utilization rate of the incident light Lib emitted from the light emitting substrate 10 and improving the problem of backlight leakage of the display substrate. Moreover, the selective reflection layer 12 can transmit the light of the specific color converted by the color conversion layer 11 (for example, red light and green light), thereby preventing the selective reflection layer 12 from affecting the light output rate of the light of the specific color converted by the color conversion layer 11. The display substrate of the embodiment of the present disclosure has a simple structure and is easy for mass production.

In some exemplary embodiments, the selective reflection layer 12 may be a composite film layer. The selective reflection layer 12 may include at least two plating films and the at least two plating films are sequentially disposed along a thickness direction of the base substrate 101. The plating films may be made of a metal or an inorganic material, for example, the plating films may include a metal such as titanium, tantalum, zirconium, niobium, aluminum, magnesium, iridium, yttrium, ytterbium, indium, tungsten, molybdenum, vanadium, nickel, silver, copper, or gold, and the plating films may include an inorganic material such as silicon, oxide, nitride, fluoride or nitrogen oxide. The selective reflection layer 12 may have a reflection effect on blue light in a band range of 415 nm to 455 nm and a transmissive effect on light in other band ranges (e.g. red light and green light) in a band range of 380 nm to 780 nm in a visible light.

In some exemplary embodiments, the selective reflection layer may be a single film layer. A manufacturing process of single film selective reflection layer is simple, which can reduce the production cost, which will not be repeated here in the embodiments of the present disclosure.

In some exemplary embodiments, as shown in FIG. 2, the selective reflection layer 12 may include at least one microlens 121, and an orthographic projection of the at least one microlens 121 on the base substrate is overlapped with the orthographic projection of the color conversion layer 11 on the base substrate 101.

In some exemplary embodiments, the at least one microlens 121 may be in a variety of shapes. For example, a shape of the at least one microlens 121 may include at least one of a conical shape, a hemispherical shape, or a pyramidal shape.

In some exemplary embodiments, the orthographic projection of the selective reflection layer on the base substrate may not be overlapped with the orthographic projection of the light transmission pattern on the base substrate 101, i.e., microlens may not be provided above the light transmission pattern.

For the selective reflection layer 12 of the display substrate according to the embodiment of the present disclosure, reflective surfaces of the selective reflection layer 12 can be increased, which improve a reflectivity of the incident light Lib (for example, blue light) which has not been converted by the color conversion layer 11, and thereby further improving the utilization rate of the incident light Lib emitted from the light emitting substrate 10.

In some exemplary embodiments, as shown in FIG. 2, the selective reflection layer 12 may include at least one microlens area, each microlens area may include one microlens 121 or multiple microlens 121 arranged at intervals. An orthographic projection of the microlens area on the base substrate 101 is overlapped with the orthographic projection of the color conversion layer 11 on the base substrate 101. For example, the orthographic projection of the microlens area on the base substrate 101 is overlapped with the orthographic projection of the first color conversion pattern 51 on the base substrate 101, and/or, the orthographic projection of the microlens area on the base substrate 101 is overlapped with the orthographic projection of the second color conversion pattern 52 on the base substrate 101, and/or, the orthographic projection of the microlens area on the base substrate 101 is overlapped with the orthographic projection of the light transmission pattern 53 on the base substrate 101.

In some exemplary embodiments, a shape of the orthographic projection of the microlens area on the base substrate 101 may include at least one of a rectangle, a polygon, a circle, a diamond, a triangle, an ellipse, and a trapezoid.

In some exemplary embodiments, as shown in FIG. 2, the selective reflection layer 12 may include a first microlens area 21, a second microlens area 22, and a third microlens area 23 and there is no overlapping area any two of an orthographic projection of the first microlens area 21 on the base substrate 101, an orthographic projection of the second microlens area 22 on the base substrate 101, and an orthographic projection of the third microlens area 23 on the base substrate 101. The first microlens area 21, the second microlens area 22, and the third microlens area 23 may each include multiple microlenses 121 arranged at intervals. The orthographic projection of the first microlens area 21 on the base substrate 101 is overlapped with the orthographic projection of the first color conversion pattern 51 on the base substrate 101, the orthographic projection of the second microlens area 22 on the base substrate 101 is overlapped with the orthographic projection of the second color conversion pattern 52 on the base substrate 101, and the orthographic projection of the third microlens area 23 on the base substrate 101 is overlapped with the orthographic projection of the light transmission pattern 53 on the base substrate 101.

In some exemplary embodiments, a density of microlenses 121 in the first microlens area 21, a density of microlenses 121 in the second microlens area 22, and a density of microlenses 121 in the third microlens area 23 may be different. The display substrate of the embodiment of the present disclosure further improves the utilization rate of the incident light Lib emitted from the light emitting substrate 10 by adjusting the density of the microlenses 121 in the first microlens area 21, the density of the microlenses 121 in the second microlens area 22 and the density of the microlenses 121 in the third microlens area 23 to adjust the reflectivity of the incident light Lib which has not been converted by the color conversion layer 11 by the microlenses 121 in the first microlens area 21, the microlenses 121 in the second microlens area 22, and the microlenses 121 in the third microlens area 23. For example, the density of the microlenses 121 in the second microlens area 22 is greater than the density of the microlenses 121 in the first microlens area 21. Since a conversion rate of the blue incident light Lib into the green light Lg through conversion by the second color conversion pattern 52 is lower than a conversion rate of the blue incident light Lib into the red light Lr through conversion by the first color conversion pattern 51, the display substrate of the embodiment of the present disclosure further improves the utilization rate of the incident light Lib emitted from the light emitting substrate 10 by increasing the density of the microlenses 121 in the second microlens area 22 to increase a reflectivity of the microlenses 121 in the second microlens area 22 for the incident light Lib which has not been converted by the second color conversion pattern 52.

In some exemplary embodiments, the density of the microlenses 121 in the first microlens area 21, the density of the microlenses 121 in the second microlens area 22, and the density of the microlenses 121 in the third microlens area 23 may be same, which will not be repeated here in the embodiments of the present disclosure.

In some exemplary embodiments, a dimension of the microlenses 121 in the first microlens area 21, a dimension of the microlenses 121 in the second microlens area 22, and a dimension of the microlenses 121 in the third microlens area 23 may be same or different. For example, a height of the microlenses 121 in the first microlens area 21, a height of the microlenses 121 in the second microlens area 22, a height of the microlenses 121 in the third microlens area 23 are different; and/or, an area and/or a shape of an orthographic projection of the microlenses 121 in the first microlens area 21 on the base substrate 101, an area and/or a shape of an orthographic projection of the microlenses 121 in the second microlens area 22 on the base substrate 101, and an area and/or a shape of an orthographic projection of the microlenses 121 in the third microlens area 23 on the base substrate 101 are different.

In some exemplary embodiments, the shape of the microlenses 121 in the first microlens area 21, the shape of the microlenses 121 in the second microlens area 22, the shape of the microlenses 121 in the third microlens area 23 may be same, which will not be repeated here in the embodiments of the present disclosure.

In some exemplary embodiments, as shown in FIG. 2, the selective reflection layer 12 is disposed on a surface of the cover plate 13 away from the base substrate 101. The microlenses 121 of the selective reflection layer 12 protrude in a direction away from the base substrate 101. Surfaces of the microlenses 121 away from the base substrate 101 may be in contact with a surface of the color resistance layer 14 close to the base substrate 101, or a first gap may be provided between the surfaces of the microlenses 121 away from the base substrate 101 and the surface of the color resistance layer 14 close to the base substrate 101. Multiple microlenses 121 make a surface of the selective reflection layer 12 away from the base substrate 101 uneven.

FIG. 4 is a second cross-sectional view of a display substrate according to an embodiment of the present disclosure. In some exemplary embodiments, as shown in FIG. 4, the selective reflection layer 12 is disposed on a surface of the color resistance layer 14 close to the base substrate 101. The microlenses 121 of the selective reflection layer 12 protrude in a direction close to the base substrate 101. Surfaces of the microlenses 121 close to the base substrate 101 may be in contact with a surface of the cover plate 13 away from the base substrate 101, or a second gap may be provided between the surfaces of the microlenses 121 close to the base substrate 101 and the surface of the cover plate 13 away from the base substrate 101. The multiple microlenses 121 make a surface of the selective reflection layer 12 close to the base substrate 101 uneven.

In the selective reflection layer 12 of the display substrate according to the embodiment of the present disclosure, reflective surfaces of the selective reflection layer 12 can be improved, which improve the reflectivity of the incident light Lib (for example, blue light) that has not been converted by the color conversion layer 11, and thereby further improving the utilization rate of the incident light Lib emitted from the light emitting substrate 10.

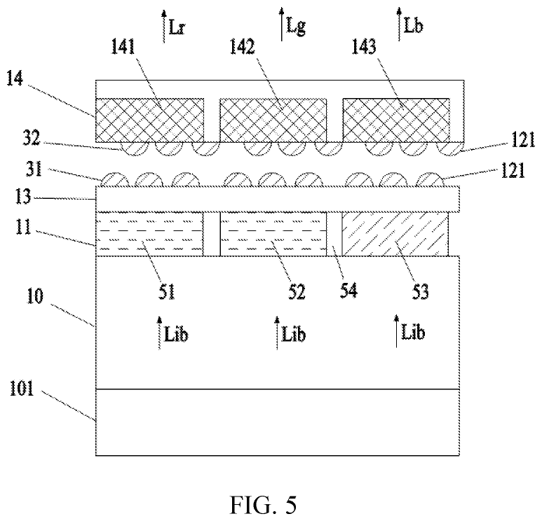

FIG. 5 is a third cross-sectional view of a display substrate according to an embodiment of the present disclosure. In some exemplary embodiments, as shown in FIG. 5, the display substrate of the embodiment of the present disclosure may include a first selective reflection layer 31 and a second selective reflection layer 32. The first selective reflection layer 31 is provided on a surface of the cover plate 13 away from the base substrate 101. The second selective reflection layer 32 is provided on a surface of the color resistance layer 14 close to the base substrate 101. The first selective reflection layer 31 and the second selective reflection layer 32 each include at least one microlens 121. An orthographic projection of the microlenses 121 in each of the first selective reflection layer 31 and the second selective reflection layer 32 on the base substrate 101 is overlapped with an orthographic projection of the color conversion layer 11 on the base substrate 101. For example, the orthographic projection of the microlenses 121 in each of the first selective reflection layer 31 and the second selective reflection layer 32 on the base substrate 101 is overlapped with an orthographic projection of the first color conversion pattern 51 on the base substrate 101, and/or the orthographic projection of the microlenses 121 in each of the first selective reflection layer 31 and the second selective reflection layer 32 on the base substrate 101 is overlapped with an orthographic projection of the second color conversion pattern 52 on the base substrate 101, and/or the orthographic projection of the microlenses 121 in each of the first selective reflection layer 31 and the second selective reflection layer 32 on the base substrate 101 is overlapped with an orthographic projection of the light transmission pattern 53 on the base substrate 101.

In some exemplary embodiments, as shown in FIG. 5, the microlenses 121 of the first selective reflection layer 31 protrude in a direction away from the base substrate 101. A third gap is provided between surfaces of the microlenses 121 of the first selective reflection layer 31 away from the base substrate 101 and the surface of the color resistance layer 14 close to the base substrate 101. The microlenses 121 of the first selective reflection layer 31 make a surface of the first selective reflection layer 31 away from the base substrate 101 uneven.

In some exemplary embodiments, as shown in FIG. 5, the microlenses 121 of the second selective reflection layer 32 protrude in a direction close to the base substrate 101. A fourth gap is provided between surfaces of the microlenses 121 of the second selective reflection layer 32 close to the base substrate 101 and the surface of the cover plate 13 away from the base substrate 101. The microlenses 121 of the second selective reflection layer 32 make a surface of the second selective reflection layer 32 close to the base substrate 101 uneven.

In some exemplary embodiments, as shown in FIG. 5, the microlenses 121 of the first selective reflection layer 31 and the microlenses 121 of the second selective reflection layer 32 are alternately disposed in a direction parallel to the base substrate 101. For example, An orthographic projection of centers of the microlenses 121 of the first selective reflection layer 31 on the base substrate 101 is overlapped with an orthographic projection of intervals between the microlenses 121 of the second selective reflection layer 32 on the base substrate 101. An orthographic projection of centers of the microlenses 121 of the second selective reflection layer 32 on the base substrate 101 is overlapped with an orthographic projection of intervals between the microlenses 121 of the first selective reflection layer 31 on the base substrate 101.

The first selective reflection layer 31 and the second selective reflection layer 31 of the aforementioned structures in the display substrate according to the embodiment of the present disclosure can improve the reflectivity of the incident light Lib (for example, blue light) which has not been converted by the color conversion layer 11, thereby further improving the utilization rate of the incident light Lib emitted from the light emitting substrate 10.

An embodiment of the present disclosure further provides a method for manufacturing a display substrate, including:
forming a light emitting substrate on a base substrate and the light emitting substrate is configured to emit incident light;
forming a color conversion layer on a side of the light emitting substrate away from the base substrate and the color conversion layer is configured to convert the incident light emitted from the light emitting substrate into light of a specific color; and forming a selective reflection layer on a side of the color conversion layer away from the base substrate and the selective reflection layer is configured to reflect incident light which has not been converted by the color conversion layer to the color conversion layer and to transmit light of a specific color converted by the color conversion layer.

The method for manufacturing the display substrate according to the embodiment of the present disclosure has simple process and low cost, and the manufactured display substrate can improve the reflectivity of the incident light Lib (e.g. blue light) which has not been converted by the color conversion layer, thereby further improving the utilization rate of the incident light Lib emitted by the light emitting substrate.

An embodiment of the present disclosure further provides a display device, which includes any one of the aforementioned display substrates. The display device may be any product or component with a display function, such as a mobile phone, a tablet computer, a television, a display, a laptop computer, a digital photo frame, or a navigator.

Although the implementations disclosed in the present disclosure are described as above, the described contents are only implementations, which are configured to facilitate the understanding of the present disclosure, and are not intended to limit the present invention. Any skilled person in the art to which the present disclosure pertains may make any modifications and variations in forms and details of implementations without departing from the spirit and scope of the present disclosure. However, the patent protection scope of the present invention should be subject to the scope defined by the appended claims.

1. A display substrate, comprising:
a base substrate;
a light emitting substrate disposed on the base substrate and the light emitting substrate being configured to emit incident light;
a color conversion layer disposed at a side of the light emitting substrate away from the base substrate and the color conversion layer being configured to convert the incident light emitted from the light emitting substrate into light of a specific color; and
a selective reflection layer disposed on a side of the color conversion layer away from the base substrate and the selective reflection layer being configured to reflect incident light which has not been converted by the color conversion layer to the color conversion layer, and to transmit the light of the specific color converted by the color conversion layer.

2. The display substrate according to claim 1, wherein the selective reflection layer comprises microlenses and an orthographic projection of the microlenses on the base substrate is overlapped with an orthographic projection of the color conversion layer on the base substrate.

3. The display substrate according to claim 2, wherein a shape of the microlenses comprises at least one of cone, hemisphere or pyramid.

4. The display substrate according to claim 2, wherein densities of the microlenses are different.

5. The display substrate according to claim 4, wherein the selective reflection layer comprises a first microlens area and a second microlens area, each of the first microlens area and the second microlens area comprises at least one microlens, the color conversion layer comprises a first color conversion pattern and a second color conversion pattern, the first color conversion pattern is configured to convert the incident light emitted from the light emitting substrate into red light, the second color conversion pattern is configured to convert the incident light emitted from the light emitting substrate into green light, an orthographic projection of the first microlens area on the base substrate is overlapped with an orthographic projection of the first color conversion layer on the base substrate, an orthographic projection of the second microlens area on the base substrate is overlapped with an orthographic projection of the second color conversion layer on the base substrate, and a density of the at least one microlens in the second microlens area is greater than a density of the at least one microlens in the first microlens area.

6. The display substrate according to claim 2, further comprising a cover plate, wherein the cover plate is disposed on the side of the color conversion layer away from the base substrate and the selective reflection layer is disposed on a surface of the cover plate away from the base substrate.

7. The display substrate according to claim 6, wherein the microlenses protrude in a direction away from the base substrate.

8. The display substrate according to claim 7, further comprising a color resistance layer, wherein the color resistance layer is disposed on a side of the selective reflection layer away from the base substrate, surfaces of the microlenses away from the base substrate is in contact with a surface of the color resistance layer close to the base substrate, or a first gap is provided between the surfaces of the microlenses away from the base substrate and the surface of the color resistance layer close to the base substrate.

9. The display substrate according to claim 2, further comprising a color resistance layer, wherein the color resistance is disposed on a side of the selective reflection layer away from the base substrate and the selective reflection layer is disposed on a surface of the color resistance layer close to the base substrate.

10. The display substrate according to claim 9, wherein the microlenses protrude in a direction close to the base substrate.

11. The display substrate according to claim 10, further comprising a cover plate, wherein the cover plate is disposed between the selective reflection layer and the color conversion layer, surfaces of the microlenses close to the base substrate is in contact with a surface of the cover plate away from the base substrate, or a second gap is provided between the surfaces of the microlenses close to the base substrate and the surface of the cover plate away from the base substrate.

12. The display substrate according to claim 1, further comprising a color resistance layer and a cover plate, wherein the color resistance layer is disposed on a side of the color conversion layer away from the base substrate, and the cover plate is disposed on a side of the cover plate away from the base substrate, the display substrate comprises a first selective reflection layer and a second selective reflection layer, the first selective reflection layer is disposed on a surface of the cover plate away from the base substrate, and the second selective reflection layer is disposed on a surface of the color resistance layer close to the base substrate.

13. The display substrate according to claim 12, wherein each of the first selective reflection layer and the second selective reflection layer comprises microlenses, the microlenses of the first selective reflection layer protrude in a direction away from the base substrate, and the microlenses of the second selective reflection layer protrude in a direction close to the base substrate.

14. The display substrate according to claim 13, wherein the microlenses of the first selective reflection layer and the microlenses of the second selective reflection layer are alternately disposed in a direction parallel to the base substrate.

15. The display substrate according to claim 13, wherein a third gap is provided between surfaces of the microlenses of the first selective reflection layer away from the base substrate and the surface of the color resistance layer close to the base substrate.

16. The display substrate according to claim 13, wherein a fourth gap is provided between surfaces of the microlens of the second selective reflection layer close to the base substrate and the surface of the cover plate away from the base substrate.

17. The display substrate according to claim 1, wherein the selective reflection layer comprises at least two plating films and the at least two plating films are disposed sequentially along a thickness direction of the base substrate.

18. The display substrate according to claim 17, wherein the plating films are made of a metal or an inorganic material; or
the plating films comprise at least one of titanium, tantalum, zirconium, niobium, aluminum, magnesium, iridium, yttrium, ytterbium, indium, tungsten, molybdenum, vanadium, nickel, silver, copper and gold; or
the plating films comprise at least one of silicon, oxide, nitride, fluoride, or nitrogen oxide.

19-20. (canceled)

21. A display device, comprising the display substrate according to claim 1.

22. A method for manufacturing a display substrate, comprising:
forming a light emitting substrate on the base substrate and the light emitting substrate being configured to emit incident light;
forming a color conversion layer on a side of the light emitting substrate away from the base substrate and the color conversion layer being configured to convert the incident light emitted from the light emitting substrate into light of a specific color; and
forming a selective reflection layer on a side of the color conversion layer away from the base substrate and the selective reflection layer being configured to reflect the incident light which has not been converted by the color conversion layer to the color conversion layer and to transmit the light of the specific color converted by the color conversion layer.
